(19) United States
(12) Patent Application Publication
(10) Pub. No.: US 2012/0249152 A1
(43) Pub. Date: Oct. 4, 2012

(54) CHARGING/DISCHARGING DETERMINATION APPARATUS AND COMPUTER-READABLE NON-TRANSITORY MEDIUM STORING CHARGING/DISCHARGING DETERMINATION PROGRAM

(76) Inventors: Yasuyuki NISHIBAYASHI, Kawasaki-shi (JP); Yoshihiro Oba, Kawasaki-shi (JP); Kotaro Ise, Kawasaki-shi (JP); Keiichi Teramoto, Tokyo (JP); Takahisa Wada, Yokohama-shi (JP)

(21) Appl. No.: 13/431,739

(22) Filed: Mar. 27, 2012

(30) Foreign Application Priority Data
Mar. 28, 2011 (JP) 2011-069146

(51) Int. Cl. G01N 27/417

(52) U.S. Cl. 324/430

(57) ABSTRACT

According to one exemplary embodiment, a charging/discharging determination apparatus includes: a receiving module which receives information of a rated capacity of a battery; and a determination module which determines that charging or a discharge of the battery is permitted if an absolute value of a difference between the rated capacity and a measured capacity which is an actual capacity of the battery is within a threshold value.

### CROSS REFERENCE TO RELATED APPLICATION(S)

The application is based upon and claims the benefit of priority from Japanese Patent Application No. 2011-069146 filed on Mar. 28, 2011; the entire content of which are incorporated herein by reference.

### FIELD

Embodiments described herein relate generally to a charging/discharging determination apparatus and a computer-readable non-transitory medium storing a charging/discharging determination program.

### BACKGROUND

In recent years, the smart grid technology has been being developed enthusiastically to provide next-generation power networks.

In smart grids, power plants and a natural energy power generation facilities supply power to homes etc. and the homes etc. consume power. Battery systems store excess (non-consumed) parts of supplied power. If the power supplied from the power plants and a natural energy power generation facilities is insufficient, the battery systems release parts of the stored electric energy to compensate for the shortage power.

Each battery system is equipped with a power conditioning system (PCS) which is connected to plural batteries and performs charging/discharge control thereon.

In battery systems, the PCS is kept settled for a long time whereas the batteries are replaced in shorter periods than the PCS.

Batteries are manufactured so as to have predetermined rated capacities. However, since a battery is manufactured by causing various chemical reactions, manufactured batteries may have capacities that are much different from the rated capacity. Furthermore, batteries may be reused many times and reused batteries may have actual capacities that are much different from their rated capacities. If a PCS charges or discharges a battery whose actual capacity is much different from its rated capacity, it may cause a serious accident such as a power failure or a fire.

Whereas a battery is given a long life as long as it is charged with its State of Charge (SOC) kept within a prescribed range, its life is shortened if it is charged in such a manner that its State of Charge is made larger than or smaller than the prescribed range. Therefore, if charging and discharging are performed repeatedly without taking lifetime elongation of a battery into consideration, the battery runs down early. If batteries are used in this manner, they need to be replaced at high frequencies, possibly rendering the power system unstable.

### BRIEF DESCRIPTION OF THE DRAWINGS

Exemplary embodiments of the present invention will be described in detail based on the following figures, wherein:

FIG. 1 shows a system according to an embodiment;

FIG. 2 is a block diagram of a battery system according to the embodiment;

FIG. 3 is a block diagram showing the configuration of a charging/discharging determination apparatus according to the embodiment;

FIG. 4 is a graph showing how chargeable/dischargeable times are determined from a State of Charge (SOC) curve;

FIG. 5 is a block diagram of an EMS used in the embodiment;

FIG. 6 shows a communication message relating to excess/shortage electric energy information used in the embodiment;

FIG. 7 shows a communication message relating to a charging/discharge permission determination result used in the embodiment;

FIG. 8 shows an operation sequence of the system according to the embodiment;

FIG. 9 is a flowchart of a process which is executed by the charging/discharging determination apparatus according to the embodiment;

FIGS. 10A to 10C illustrate a lifetime elongation determination and an individual battery abnormality determination which are performed in the battery system according to the embodiment;

FIG. 11 is a block diagram of an EV system.

### DETAILED DESCRIPTION OF THE EXEMPLARY EMBODIMENTS

According to one embodiment, a charging/discharging determination apparatus includes: a receiving module which receives information of a rated capacity of a battery; and a determination module which determines that charging or a discharge of the battery is permitted if an absolute value of a difference between the rated capacity and a measured capacity which is an actual capacity of the battery is within a threshold value.

An embodiment will be hereinafter described with reference to the drawings. The same units, sections, or the like in the drawings will be given the same reference symbol and will not be described redundantly.

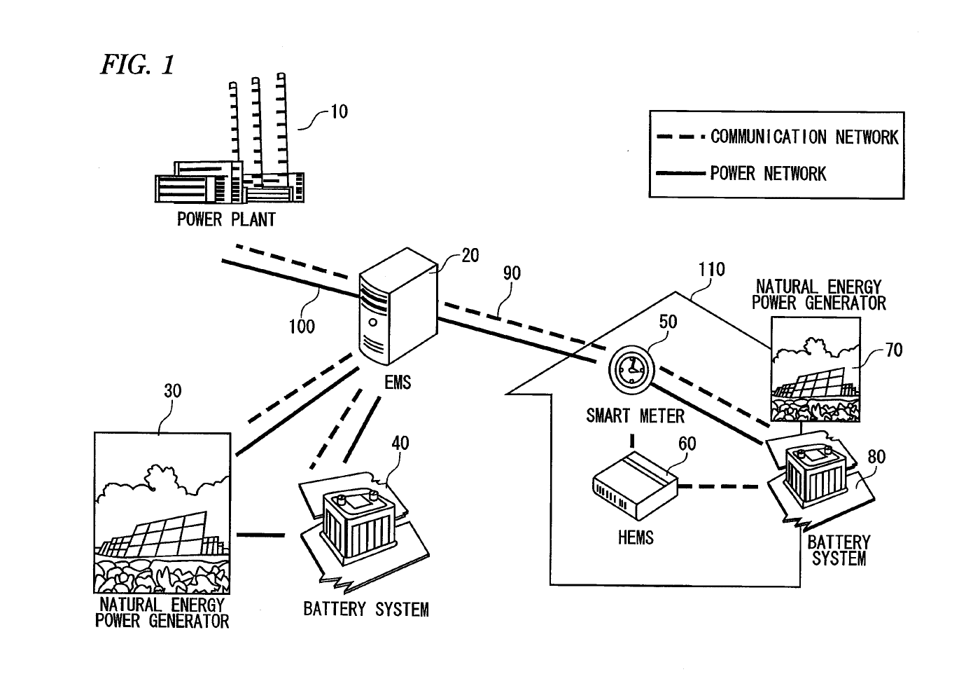

FIG. 1 shows a system according to an embodiment.

The system according to the embodiment includes a power plant (power supply command center) 10, an energy management system (EMS) 20, a natural energy power generator 30, a battery system 40, and a house 110. The house 110 is equipped with a smart meter 50, a home energy management system n (HEM) 60, a natural energy power generator 70, and a battery system 80.

The power plant 10, the EMS 20, the natural energy power generator 30, the battery system 40, and the home 110 are connected to each other by a power network 100 and a communication network 90.

In the house 110, the smart meter 50, the HEM 60, the natural energy power generator 70, and the battery system 80 are connected to each other by the power network 100 and the communication network 90.

The power plant 10 generates power through thermal power generation or nuclear power generation, or the like, and supplies the generated power to the house 110 over the power network 100.

The natural energy power generator 30 generates power using natural energy such as wind energy or solar energy, and supplies the generated power to the house 110 over the power network 100. The system according to the embodiment can be operated efficiently by lowering a load of the power plant 10 because the natural energy power generator 30 also supplies power.

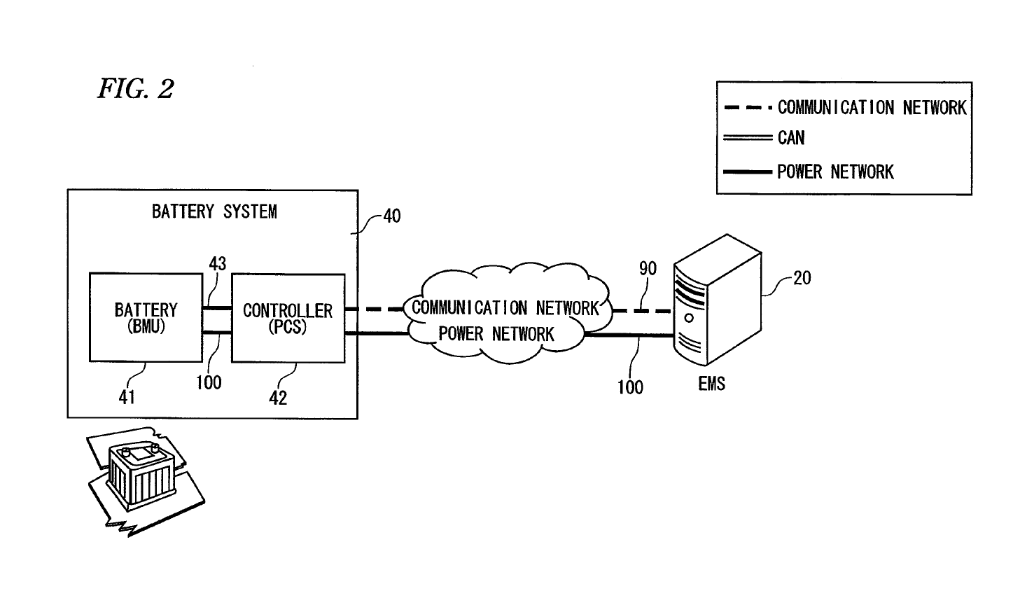

The battery system 40 stores an excessive part of the power generated by the power plant 10 and the natural energy power generator 30. The excess power is a residual part, not supplied to power demand entities over the power network 100, of the power generated by the power plant 10 and the natural energy power generator 30. In the embodiment, the house 110 is an example power demand entity. The battery system 40 supplies power stored therein to the house 110. As shown in FIG. 2, the battery system 40 is equipped with a battery (battery management unit (BMU)) 41 and a controller 42 (power conditioning system (PCS)). The controller 42 is equipped with a charging/discharging determination apparatus 420. The battery 41, the controller 42, and the charging/discharging determination apparatus 420 will be described later.

The EMS 20 controls the entire system of FIG. 1. More specifically, the EMS 20 performs, via the power network 100 and the communication network 90, a control of power to be supplied from the power plant 10 and the natural energy power generator 30, a control of load power to be consumed in the house 110, and a control of excess power to be stored in the battery system 40. If the absolute value of the difference between power (actual value) supplied from the power plant 10 or the natural energy power generator 30 and planned supply power (planned value) is larger than a prescribed threshold value, the EMS 20 instructs the power plant 10 to increase the supply power. A detailed configuration and functions of the EMS 20 will be described later.

The smart meter 50, which is installed in the house 110, measures electric energy consumed in the house 110 and informs a metering data management system (MDMS; not shown in FIG. 1) of a measurement result. The MDMS is provided in an electric power company, for example. The EMS 20 cooperates with the MDMS to calculate a total electric energy consumption of the house 110.

The natural energy power generator 70, which is installed in the house 110, generates power using natural energy such as wind energy or solar energy. The generated power is consumed in the house 110 or stored in the battery system 80.

The battery system 80 is installed in the house 110. The battery system 80 is different from the battery system 40 in being installed in the house 110 but have the same functions as the latter. That is, the battery system 80 is equipped with a battery (BMU) 41 and a controller (PCS) 42. The battery system 80 stores part of power that is supplied from the power plant 10 and the natural energy power generator 30 or part of power generated by the natural energy power generator 70 of the house 110.

The HEMS 60 adjusts and controls the electric energy consumption in the house 110.

Although the system of FIG. 1 is provided with the single power plant 10, EMS 20, natural energy power generator 30, battery system 40, and house 110, each of them may be provided in plurality.

FIG. 2 is a block diagram of the battery system 40.

The battery system 40 is equipped with a battery (BMU) 41 and a controller (PCS) 42.

The battery (BMU) 41 is equipped with a battery pack having plural battery cells and an internal processor which manages the state of the battery pack. The battery (BMU) 41 charges or discharges power according to a charging/discharge instruction from the controller (PCS) 42.

The battery 41 informs the controller 42 of its battery information such as a rated voltage, a rated capacity, maximum charging/discharge currents, a state of charge (SOC), and a state of health (SOH). These pieces of information need not always be communicated together and may be communicated divisionally in the form of plural messages. The pieces of information constituting the battery information are not limited to the above-described ones. The battery information includes, as unique, fixed pieces of information (not variable with time), pieces of characteristic information such as a rated voltage, a rated capacity, a charging/discharge cut-off voltage, an upper limit temperature, a lower limit temperature, maximum charging/discharge currents, and an optimum State of Charge range. The battery information also includes, as variable pieces of information that vary with the passage of time during operation of the battery 41, pieces of state information such as an SOH, an SOC, a charging/discharge current, and a charging/discharge voltage. It is preferable that at least variable pieces of information (pieces of characteristic information) be communicated regularly or in response to a request from the EMS 20 which is provided outside the battery system 40, for real-time update.

The rated capacity (unit: ampere hour (Ah)) is a standard amount of electricity that can be output from a completely charged state under a prescribed condition temperature, charging current, and cut-off voltage). The rated voltage (unit: volt (V)) is voltage information to be used for indication of a battery voltage, and is called a nominal voltage in JIS D0114 (electric vehicle terms (batteries)). In the general constant current charging method, the current flowing into the battery cells of a battery pack is kept constant (linear charging) until the State of Charge (SOC) reaches a prescribed threshold value. A maximum value of such a current at the time of charging is defined as a maximum charging current (unit: ampere (A)) and a maximum value of such a current at the time of a discharge is defined as a maximum discharge current (unit: ampere (A)). The SOC threshold voltage which dictates the end of a constant current state depends on the battery type.

The controller (PCS) 42 performs a charging/discharge control on the battery (BMU) 41 and exchanges information with the battery 41. For example, a controller area network (CAN) 43 is used for information communication between the battery 41 and the controller 42. Alternatively, any of other communication media such as an Ethernet (registered trademark) may be used for such information communication.

The controller (PCS) 42 has a communication function and communicates with the EMS 20 which is provided in the power network 100. The controller 42 sends battery information of the battery 41 to the EMS 42 regularly over the communication network 90, whereby the EMS 42 can be informed, in real time, of the battery information which varies with the passage of time. The battery information varies with the passage of time because the battery has a feature of natural discharge.

Furthermore, the controller (PCS) 42 performs AC-DC/DC-AC conversion and suppression of a voltage variation for power to be stored in or power supplied from the battery 41. Alternatively, AC-DC/DC-AC conversion and suppression of a voltage variation may be performed on an external processor that is connected to the controller 42.

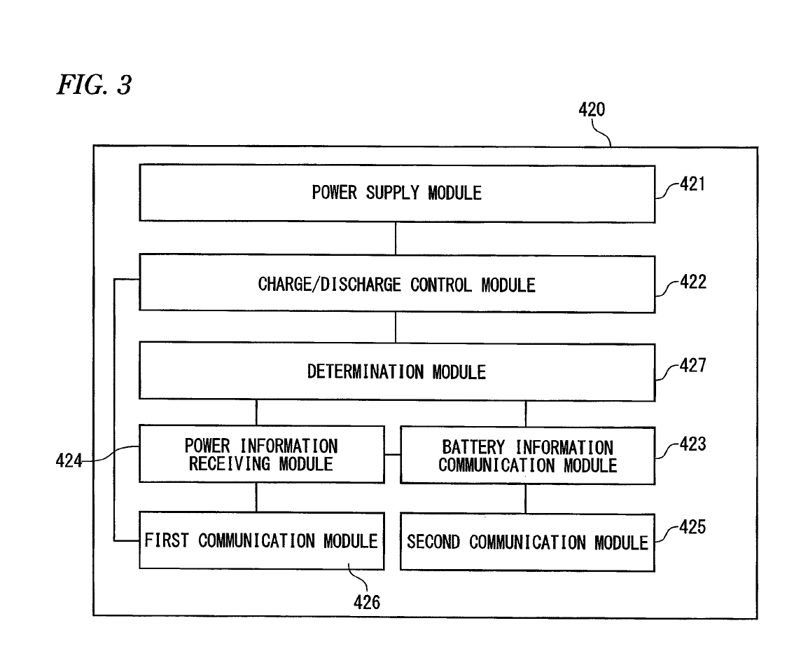

It is preferable that the controller 42 be equipped with the charging/discharging determination apparatus 420 shown in FIG. 3.

FIG. 3 is a block diagram showing the configuration of the charging/discharging determination apparatus 420 according to the embodiment.

The charging/discharging determination apparatus 420 corresponds to the controller 42 of the battery system 20 shown in FIG. 2.

The charging/discharging determination apparatus 420 receives battery information of the battery 41 and determines whether to permit charging or a discharge of the battery 41. Furthermore, the charging/discharging determination apparatus 420 performs charging/discharge control according to a determination result.

The charging/discharging determination apparatus 420 is equipped with a power supply module 421, a charging/discharge control module 422, a determination module 427, a battery information receiving module 424, a power information communication module 423, a first communication module 426, and a second communication module 425.

The first communication module 426 is an interface for communication with the battery (BMU) 41 and is, for example, a CAN 43 which complies with CAN which is a standard interface standard for batteries (BMUs). Alternatively, the first communication module 426 may be a communication medium such as an Ethernet (registered trademark).

The power supply module 421 performs power control on the battery (BMU) 41 according to an instruction supplied from the charging/discharge control module 422 (described later). The power supply module 421 also performs AC-DC/DC-AC conversion, detection of a frequency of power, detection and suppression of a voltage variation, etc.

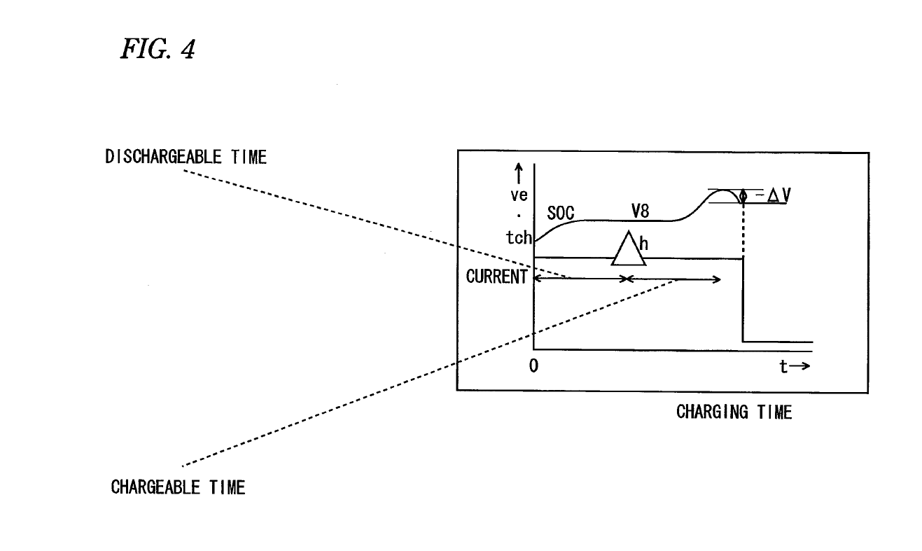

The battery information receiving module 424 receives battery information of the battery (BMU) 41 via the first communication module 426. The battery information receiving module 424 may calculate chargeable/dischargeable times (unit: hour (h)) of the battery (BMU) 41 based on a received SOC using a graph shown in FIG. 4, for example. In the constant current charging method which is a general charging method, the input/output current of the battery (BMU) 41 is constant until the SOC reached a prescribed threshold value. This constant current is a maximum charging/discharge current which is one piece of characteristic information of the battery (BMU) 41. In the constant current charging method, the charging current becomes very small after the SOC exceeds the threshold value.

For example, as in the example of FIG. 4, assume that the SOC range where the input/output current of the battery 41 is kept at the maximum charging/discharge current is from 0% to 90% and that the SOC is currently at 50% (indicated by symbol “Δ” in FIG. 4). A time that is necessary to perform charging of the remaining 40% of SOC can be estimated as a chargeable time as indicated by a solid-line double arrow shown in FIG. 4. On the same assumptions, a time that is necessary to perform a discharge of 50% can also be estimated as a dischargeable time. The SOC range where the input/output current of the battery 41 is kept at the maximum charging/discharge current depends on the battery type and is not limited to 0% or 90%.

The second communication module 425 can be implemented as a wired communication medium such as an optical fiber, a telephone line, or an Ethernet (registered trademark) or a wireless communication medium. That is, the second communication module 425 is not limited to a particular communication medium.

The power information communication module 423 receives a communication message relating to excess/shortage electric energy information via the second communication module 425. This communication message indicates the difference between a planned value (managed by the EMS 20 or the smart meter 50) and an actual value of power supplied from the power plant 10 and the natural energy power generator 30 managed by the EMS 20 or the smart meter 50. The excess/shortage electric energy information is used for calculating a predicted SOC which relates to lifetime elongation of the battery 41.

The charging/discharge control module 422 starts a charging or discharge control on the battery (BMU) 41 after the determination module 427 makes a determination as to whether to permit charging or a discharge.

The determination module 427 determines whether to permit charging or a discharge. The determination module 427 makes this determination by performing one or both of an individual battery abnormality determination and a lifetime elongation determination.

In the individual battery abnormality determination, it is determined whether or not the absolute value of the difference between a measured capacity (actual capacity) and the rated capacity of the battery 41 is within a prescribed threshold value. If the absolute value is within the prescribed threshold value, it is determined that charging or a discharge of the battery (BMU) 41 should be permitted. If the absolute value is not within the prescribed threshold value, it is determined that charging or a discharge of the battery 41 should not be permitted. For example, the individual battery abnormality determination is made when the battery 41 is newly connected. For example, a measured capacity can be obtained by charging or discharging the battery 41 after discharging or charging the battery 41 completely. For example, if the battery 41 has a State of Charge that is larger than the prescribed threshold value, a measured capacity is obtained by discharging the battery 41 completely after charging the battery 41 completely. If the battery 41 has a State of Charge that is smaller than the prescribed threshold value, a measured capacity is obtained by charging the battery 41 completely after discharging the battery 41 completely.

As for the lifetime elongation determination, whether to permit charging or a discharge of the battery 41 is determined depending on whether or not a predicted State of Charge which is calculated based on a State of Charge (SOC) and excess/shortage electric energy information is within a prescribed range (i.e., an optimum State of Charge range for lifetime elongation of the battery 41 (described later)). Charging or a discharge is permitted if the predicted State of Charge is within the prescribed range, and is not permitted if the predicted State of Charge is not within the prescribed range. The lifetime elongation determination may be made subsequent to the individual battery abnormality determination when the battery 41 is connected. Alternatively, lifetime elongation determination may be made solely when, for example, charging or a discharge of the battery 41 is requested.

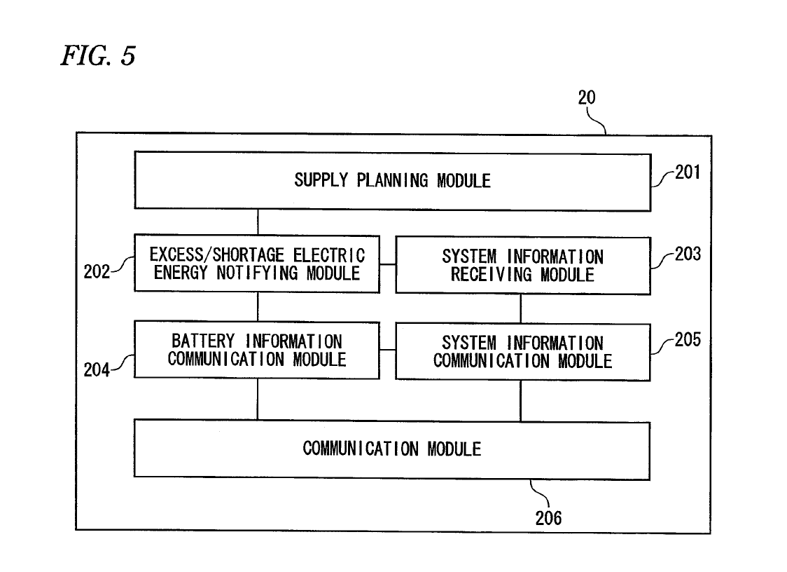

FIG. 5 is a block diagram of the EMS 20.

The EMS 20 is equipped with a supply planning module 201, a system information receiving module 203, an excess/shortage electric energy notifying module 202, a system information communication module 205, a battery information communication module 204, and a communication module 206.

The supply planning module 201 manages planned values of power to be supplied from the power plant 10 and the natural energy power generator 30. The planned values of supply power are supply power values that are predicted to occur in the future. For example, planned values of supply power are calculated through prediction based on supply power values that occurred at the same time point in the past. Planned supply power of the natural energy power generator 30 may be calculated according to weather that is forecast to occur at the time of natural energy power generation. The supply planning module 201 also manages information necessary to calculate a delay time which is a time that it takes for the power plant 10 to change its supply power. The information necessary to calculate a delay time may be the delay time itself. For example, the delay time is a time that it takes for the power plant 10 to change the turbine rotation speed to change its supply power, and is, for example, a time from issuance of a rotation change instruction to completion of a reflection of the instruction.

The system information receiving module 203 receives, real time, an actual value of power being supplied from the power plant 10 and the natural energy power generator 30 to the house 110. For example, the system information receiving module 203 receives an actual value of supply power by receiving communication messages from the power plant 10 and the natural energy power generator 30 over the communication network 90. Alternatively, the system information receiving module 204 may receive an actual value of supply power by calculating electric energy values based on frequency variations and voltage variations obtained through monitoring via the power network 100.

The system information communication module 205 performs processing of receiving communication messages from the power plant 10 and the natural energy power generator 30. The communication messages may be such as to comply with a power information communication protocol such as IEC 61850. The system information communication module 205 may communicate with the MDMS or the smart meter 50 when, for example, planned values are determined or an actual value is received through a calculation in which a power consumption of the house 110 is taken into consideration. In this case, the system information communication module 205 communicates with the MDMS or the smart meter 50 using a remote meter-reading communication protocol such as ANSI C12.19/22.

The excess/shortage electric energy notifying module 202 notifies the charging/discharging determination apparatus 420 which is managed by the EMS 20 of excess/shortage electric energy (unit: watt hour (Wh)) of the power system. The excess/shortage electric energy can be calculated as the product of the difference between a planned value and an actual value of supply power and a delay time.

The battery information communication module 204 performs communication processing for exchanging communication messages with the charging/discharging determination apparatus 420.

The communication module 206 can be implemented as a wired communication medium such as an optical fiber, a telephone line, or an Ethernet (registered trademark). The communication module 206 is not limited to a particular communication medium.

The above-described functions of the EMS 20 ma be provided in the smart meter 50 where appropriate.

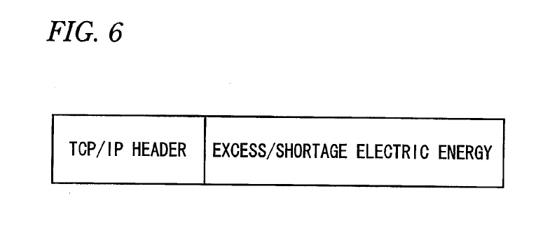

FIG. 6 shows a communication message relating to excess/shortage electric energy information which is sent from the EMS 20 to the battery system 40 (more specifically, the controller (PCS) 42 which corresponds to the charging/discharging determination apparatus 420). The communication message relating to excess/shortage electric energy information contains a Transmission control protocol/Internet protocol (TCP/IP) header and excess/shortage electric energy information. The TCP/IP header is communication control information of the TCP/IP protocol which is a standard protocol of the Internet and an intranet. As mentioned above, the excess/shortage electric energy (unit: watt hour (Wh)) is the product of the difference between a planned value and an actual value of supply power and a delay time.

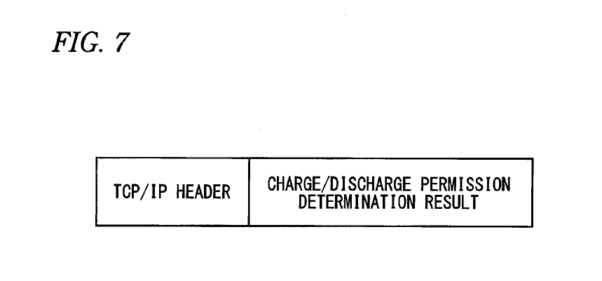

FIG. 7 shows a communication message which is sent from the battery system 40 (more specifically, the controller (PCS) 42 which corresponds to the charging/discharging determination apparatus 420) to the EMS 20 and contains a charging/discharge permission determination result. The charging/discharge permission determination result is information that is sent from the charging/discharging determination apparatus 420 to the EMS 20 when necessary, and can be omitted where appropriate.

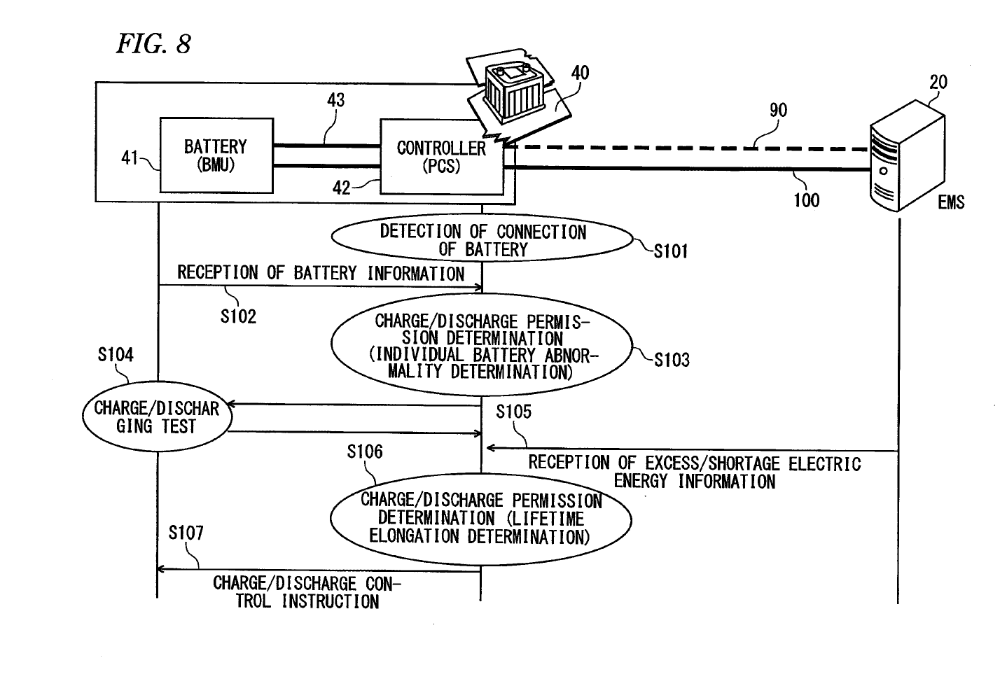

FIG. 8 shows an operation sequence of the system according to the embodiment.

After detecting connection of the battery (BMU) 41 at step S101, at step S102 the controller (PCS) 42 which operates as the charging/discharging determination apparatus 420 receives battery information (rated capacity, rated voltage, maximum charging/discharge currents, SOC, and battery optimum State of Charge range).

At step S103, the charging/discharging determination apparatus 420 performs an individual battery abnormality determination which is part of a charging/discharge permission determination. In the individual battery abnormality determination, first, at step S104, the charging/discharging determination apparatus 420 obtains a measured capacity by discharging or charging the battery 41 completely and then charging or discharging it (charging/discharging test). The charging/discharging determination apparatus 420 determines whether to permit charging or a discharge of the battery 41 by determining whether or not the absolute value of the difference between the measured capacity and the rated capacity is within a threshold value (difference check).

If it is confirmed that the battery 41 is normal, a transition is made to a lifetime elongation determination. In the lifetime elongation determination, at step S105 the charging/discharging determination apparatus 420 receives excess/shortage electric energy information from the EMS. At step S106, the charging/discharging determination apparatus 420 determines whether to permit charging or a discharge of the battery 41 by calculating a predicted State of Charge using the excess/shortage electric energy and the battery information and determining whether or not the predicted State of Charge is within the optimum State of Charge range.

If charging or a discharge is permitted by the lifetime elongation determination, at step S107 the charging/discharging determination apparatus 420 performs a charging or discharge control on the battery 41.

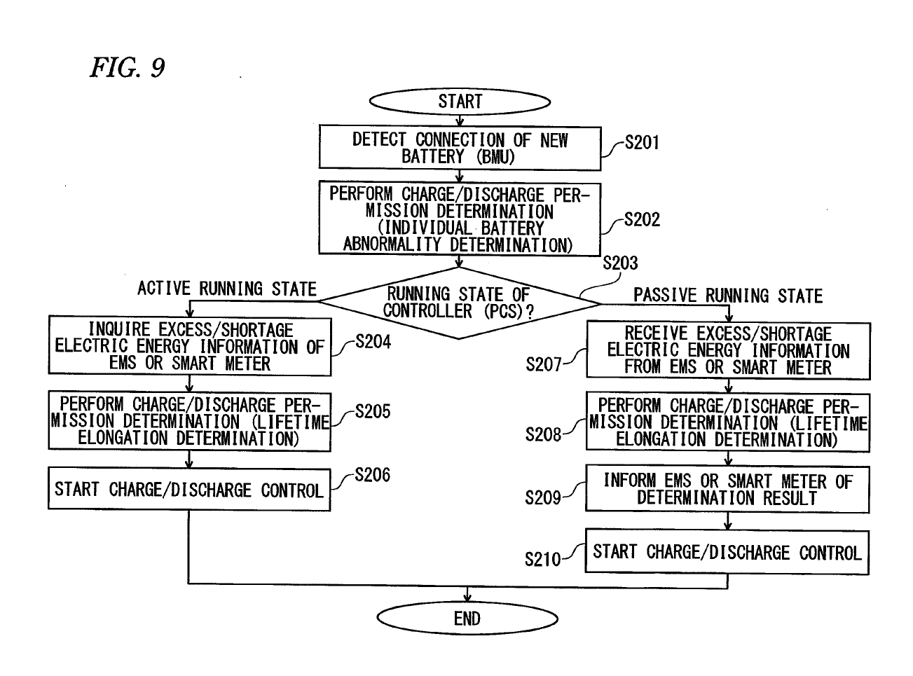

FIG. 9 is a flowchart of a process which is executed by the charging/discharging determination apparatus 420 according to the embodiment of the invention.

If the battery (BMU) 41 is newly connected to the charging/discharging determination apparatus 420 which operates as the PCS, at step S201 the charging/discharging determination apparatus 420 receives battery information (rated capacity (unit: ampere hour (Ah)), rated voltage (unit: volt (V)), maximum charging/discharge currents (unit: ampere (A)), SOC (unit: %), and battery optimum State of Charge range) via the first communication module 426. The charging/discharging determination apparatus 420 calculates a chargeable/dischargeable times (unit: hour (h)) corresponding to the SOC.

At step S202, the charging/discharging determination apparatus 420 performs an individual battery abnormality determination which is part of a charging/discharge permission determination on the battery 41.

In the individual battery abnormality determination, the charging/discharging determination apparatus 420 obtains a measured capacity (unit: ampere hour (Ah)) by causing charging and a discharge of the battery (BMU) 41. If the absolute value of the difference between the measured capacity and the rated capacity is within a threshold value, the charging/discharging determination apparatus 420 determines that the battery 41 is normal and permits charging or a discharge of the battery 41.

After charging or a discharge is permitted by the individual battery abnormality determination, the battery system 40 makes a transition to a working state in which it performs charging or a discharge while taking the status of the power system into consideration.

At step S203, the charging/discharging determination apparatus 420 determines whether it is in a passive running state in which it operates according to instructions from the EMS 20 or an active running state in which it operates on its own while recognizing the status of the power system to which it belongs.

A lifetime elongation determination of the charging/discharge permission determination can be performed in the same manner in either running state.

First, at step S204 or S207, the charging/discharging determination apparatus 420 receives excess/shortage electric energy information (unit: watt hour (Wh)) from the EMS 20 or the smart meter 50.

Then, the charging/discharging determination apparatus 420 calculates a predicted State of Charge (SOC). A predicted State of Charge can be calculated using the excess/shortage electric energy information and the battery information. The predicted State of Charge is a State of Charge that reflects an increase or decrease due to charging or a discharge for compensation for the excess/shortage electric energy. For example, a predicted State of Charge is calculated as the sum of a current SOC and the excess/shortage electric energy divided by the product of the rated voltage and the rated capacity.

At step S205 or S208, the charging/discharging determination apparatus 420 performs a lifetime elongation determination which is part of the charging/discharge permission determination based on the predicted State of Charge (unit: %).

If determining, at step S205, that charging or a discharge should be permitted, at step S206 the charging/discharging determination apparatus 420 starts a charging or discharge control.

If determining, at step S208, that charging or a discharge should be permitted, the charging/discharging determination apparatus 420 informs the EMS 20 of the determination result at step S209 and starts a charging or discharge control at step S210.

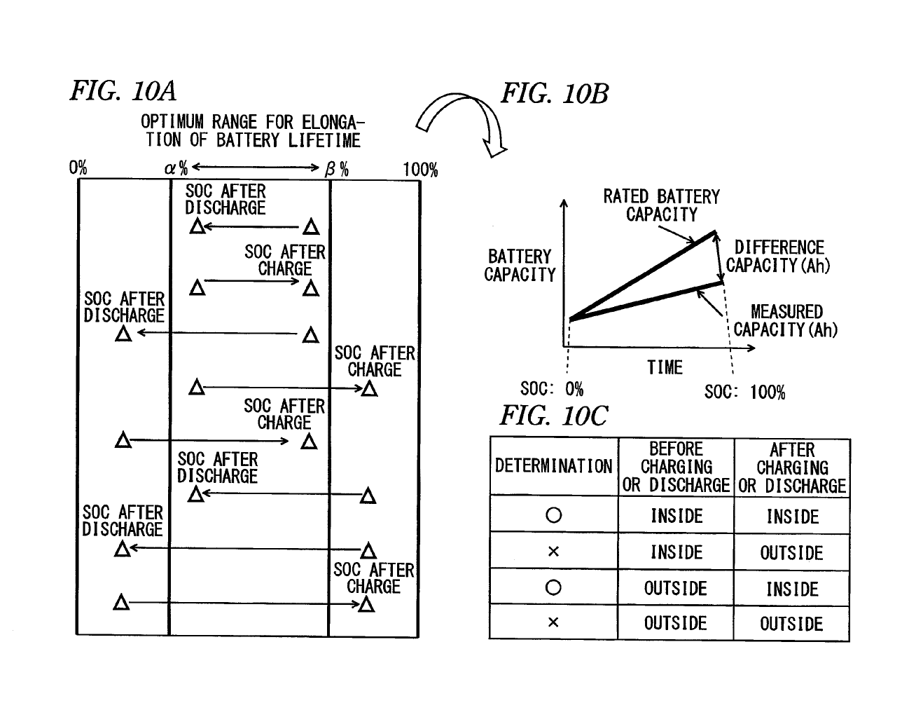

Next, the lifetime elongation determination and the individual battery abnormality determination will be described in detail with reference to FIGS. 10A to 10C.

FIGS. 10A to 10C illustrate the lifetime elongation determination and the individual battery abnormality determination which are performed in the battery system according to the embodiment.

First, the lifetime elongation determination will be described.

In general, the lifetime of the battery system 40 can be elongated by performing charging/discharge controls on the battery cells of the battery (BMU) 41 within its optimum State of Charge (SOC) range (between a lower limit α% and an upper limit β%) instead of charging the battery cells of the battery (BMU) 41 completely (SOC is 100%) or discharging them completely (SOC is 0%).

In view of the above, as shown in FIG. 10A, if the predicted State of Charge (predicted SOC) after charging or a discharge remains within its optimum range based on the optimum range information for battery lifetime elongation, it is selected as a battery system to perform charging or discharging.

A predicted SOC is determined based on excess/shortage electric energy information (mentioned above) and battery information (rated capacity, rated voltage, maximum charging/discharge currents, and current SOC).

The charging/discharging determination apparatus 420 performs a charging or discharge control on a battery whose predicted SOC is within the optimum State of Charge range that is unique to the battery.

FIG. 10C shows an example in which among four kinds of combination of a current SOC and a predicted SOC two kinds of combinations whose predicted SOCs are within the optimum range are selected by the lifetime elongation determination.

Next, the individual battery abnormality determination will be described.

FIG. 10B illustrates a control operation that is performed for the individual battery abnormality determination.

To check whether a battery is abnormal or not, it is preferable to perform a combination of a complete discharge (a state of the lower limit of current release from the battery; theoretically corresponds to an SOC value 0%) and complete charging (a state of the upper limit of current inflow to the battery; theoretically corresponds to an SOC value 100%). As shown in FIG. 10B, the difference (indicated by symbol L in FIG. 10B) between a rated capacity (theoretical value; unit: Ah) and a measured capacity (unit: Ah) that is measured through complete discharging and charging is determined. If the difference is larger than a prescribed threshold value, the battery is determined abnormal.

There are battery types in which complete charging and discharging take considerable times. It is therefore preferable to employ a test method in which complete charging is performed first and then complete discharging is performed if a current SOC is larger than a prescribed threshold value (e.g., 50%) and complete discharging is performed first and then complete charging is performed if a current SOC is smaller than the prescribed threshold value.

In calculating a measured capacity, the completely discharged state and the completely charged state may be defined as corresponding to SOC values of 10% (rather than 0%) and 80% (rather than 100%), respectively.

Instead of determining the difference between a theoretical capacity and a measured capacity, a time that is taken by a transition between a completely discharged state and a completely charged state.

According to the above-described embodiment, the battery system 40 can be operated safely and stably by checking a capacity and a State of Charge of its battery 41 before charging or a discharge. More specifically, it is possible to start operating the battery system 40 with its reliability and safety secured because a charging/discharge permission determination which consists of a lifetime elongation determination and an individual battery abnormality determination is performed when it is installed initially (i.e., the battery 41 is newly connected to the controller (PCS) 42). Furthermore, the life of the battery 41 can be elongated by performing a lifetime elongation determination where appropriate while it is in use.

Although the embodiment is directed to the case that the battery system 40 includes only one battery 41, the battery system 40 may include plural batteries 41. In the latter case, through an individual battery abnormality determination and a lifetime elongation determination, not only is whether to permit charging or a discharge of each battery 41 determined but also an optimum one may be selected from the plural batteries 41.

Although in the embodiment both of an individual battery abnormality determination and a lifetime elongation determination are performed in determining whether to permit charging or a discharge of the battery 41 of the battery system 40, charging or a discharge of the battery 41 may be permitted if only one of those determinations is performed and permission is obtained. For example, it is possible to perform an individual battery abnormality determination when the battery 41 is connected and to permit charging or a discharge of the battery 41 if it is determined normal. It is also possible to perform a lifetime elongation determination where appropriate after connection of the battery 41 and to permit charging or a discharge of the battery 41 if permission is obtained as a result of the lifetime elongation determination.

Although in the embodiment, electric energy to be stored in or supplied from the battery 41 is excess or shortage electric energy which is the product of a delay time and the difference between a planned value and an actual value of power supplied from the power plant 10 and the natural energy power generator 30, the invention is not limited to such a case. Electric energy to be stored in or supplied from the battery 41 may be electric energy that is requested be done so by an external apparatus or the like.

Although in the embodiment the charging/discharging determination apparatus 420 receives excess/shortage electric energy information from the EMS 20, it may calculate excess/shortage electric energy on its own based on voltage drops etc. occurring around it.

In the embodiment, an EV system 50 may be used in place of the battery system 40. The EV system 50 is a battery system that is mainly intended for vehicular use.

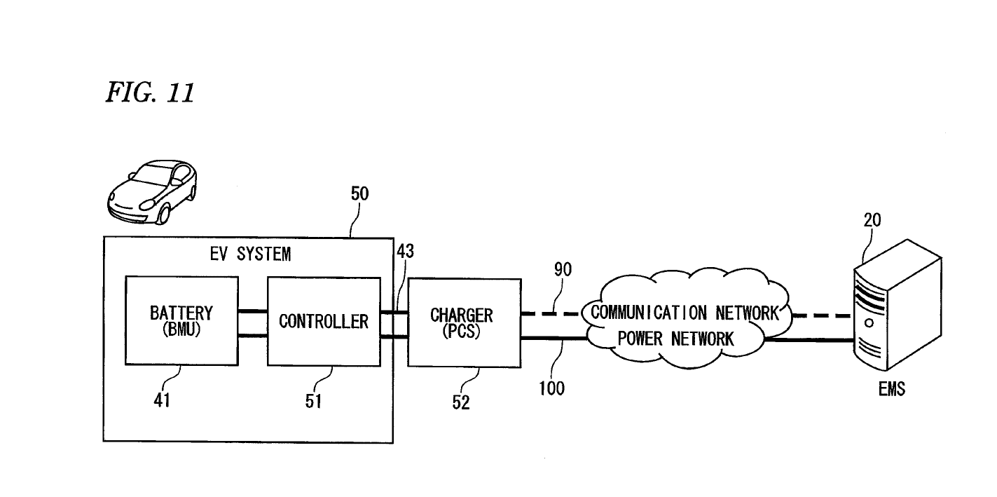

FIG. 11 shows the configuration of the EV system 50. Like the battery system 40, the EV system 50 is equipped with a battery (BMU) 41 and a controller 51. The EV system 50 is different from the battery system 40 in that a charger (PCS) 52 is connected to the EV system 50.

The controller 51 of the EV system 50 has different functions than the controller 42 of the battery system 40. More specifically, unlike the controller 42, the controller 51 of the EV system 50 has a function of relaying a charging/discharge control and an information transfer between the battery (BMU) 41 and the charger (PCS) 52 and does not have a communication function of communicating with the EMS 20. Main functions of the controller 42 of the battery system 40 are transferred to the charger 52. The functions of the charging/discharging determination apparatus 420 of the controller 42 are transferred to the charger 52. More specifically, the functions of the charging/discharging determination apparatus 420 of the controller 42 are provided in the charger 52. The functions of the charging/discharging determination apparatus 420 of the charger 52 are the same as those of the charging/discharging determination apparatus 420 of the controller 42.

Alternatively, the controller 51 of the EV system 50 may be provided with the same functions as the controller 42 of the battery system 40. That is, the controller 51 of the EV system 50 may be provided with the functions of the charging/discharging determination apparatus 420 of the controller 42.

An algorithm process relating to charging/discharging of the battery (BMU) 41 can be implemented in various forms; for example, it may be concentrated in any of the controller 42, the charger 52, the HEMS 60 in the house 110, and the EMS 20 of the power network 100. The embodiment can be realized within the same framework even if the algorithm process is implemented in any of those forms.

Although the embodiment is directed to the case that the power consumer is the house 110, a building or a factory may be a power consumer. Where a building is a power consumer, a building energy management system (BEMS) is installed in the building instead of the HEMS 60 of the house 110 and controls the power consumption in the building. Where a factory is a power consumer, a factory energy management system (FEMS) is installed in the factory and controls the power consumption in the factory.

The functions of the charging/discharging determination apparatus 420 according to the embodiment may likewise be provided in the EMS 20 which is installed in the power network 100, the HEMS 60 which is installed in the house 110, a BEMS which is installed in a building, an FEMS which is installed in a factory, or the smart meter 50.

The charging/discharging determination apparatus 420 may be implemented by using, for example, a general-purpose computer as basic hardware. That is, the power supply module 421, the charging/discharge control module 422, the power information communication module 423, the battery information receiving module 424, the second communication module 425, the first communication module 426, and the determination module 427 may be implemented by causing a processor provided in the computer to run programs. In this case, the charging/discharging determination apparatus 420 may be implemented by either pre-installing the programs in the computer or installing, in the computer, when necessary, the programs that are stored in a storage medium such as a CD-ROM or delivered over a network.

While certain exemplary embodiment has been described, the exemplary embodiment has been presented by way of example only, and is not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A charging/discharging determination apparatus comprising:
a receiving module configured to receive information of a rated capacity of a battery; and
a determination module configured to determine that charging or a discharge of the battery is permitted if an absolute value of a difference between the rated capacity and a measured capacity which is an actual capacity of the battery is within a threshold value.

2. The apparatus of claim 1, wherein the determination module is configured to determine that charging or a discharge of the battery is not permitted if the absolute value of the difference is not within the threshold value.

3. The apparatus of claim 2 further comprising:
a communication module configured to receive information of electric energy to be supplied from or stored in the battery, wherein:
the receiving module is configured to receive information of a State of Charge of the battery from the battery; and
the determination module is configured to determine that charging or a discharge of the battery is permitted if a predicted State of Charge which is calculated from the State of Charge and the electric energy is within a certain range.

4. The apparatus of claim 3, wherein the determination module is configured to determine that charging or a discharge of the battery is not permitted if the predicted State of Charge is not within the certain range.

5. The apparatus of claim 3, wherein the State of Charge of the battery is a State of Charge that is obtained before the charging/discharging determination apparatus is instructed to cause charging or a discharge of the battery.

6. The apparatus of claim 2, wherein the determination module is configured to determine whether or not the absolute value of the difference is within the threshold value when the battery is connected.

7. The apparatus of claim 1, wherein the determination module is configured to measure the measured capacity by discharging the battery after charging the battery completely or charging the battery after discharging the battery completely.

8. The apparatus of claim 3, wherein the certain range is an optimum State of Charge range for lifetime elongation of the battery.

9. The apparatus of claim 4, wherein the determination module is configured to measure the measured capacity by discharging the battery completely after charging the battery completely if the State of Charge is larger than a threshold value and by charging the battery completely after discharging the battery completely if the State of Charge is smaller than the threshold value.

10. The apparatus of claim 3, wherein the communication module is configured to receive the information of the electric energy based on a difference between a planned value and an actual value of power that is supplied from a power plant and a natural energy power generator.

11. A computer-readable non-transitory medium storing a charging/discharging determination program, the program comprising:
a receiving function of receiving information of a rated capacity from a battery; and
a determining function of determining that charging or a discharge of the battery is permitted if an absolute value of a difference between the rated capacity and a measured capacity which is an actual capacity of the battery is within a threshold value.
